(19) United States
(12) Patent Application Publication
(10) Pub. No.: US 2025/0176162 A1
(43) Pub. Date: May 29, 2025

(54) CAPACITOR AND ELECTRONIC DEVICE INCLUDING THE SAME

(71) Applicant: Samsung Electronics Co., Ltd., Suwon-si (KR)

(72) Inventors: Jinhong KIM, Suwon-si (KR); Changsoo LEE, Suwon-si (KR); Woonghyeon PARK, Suwon-si (KR); Jooho LEE, Suwon-si (KR); Yong-Hee CHO, Hwasung-si (KR)

(73) Assignee: Samsung Electronics Co., Ltd., Suwon-si (KR)

(21) Appl. No.: 18/664,776

(22) Filed: May 15, 2024

(30) Foreign Application Priority Data
Nov. 29, 2023 (KR) 10-2023-0170036
Feb. 22, 2024 (KR) 10-2024-0026040
May 3, 2024 (KR) 10-2024-0059420

(51) Int. Cl. H10B 12/00

(52) U.S. Cl. CPC H10B 12/315; H10B 12/033

(57) ABSTRACT

A capacitor includes a first electrode, a second electrode disposed to face the first electrode, a dielectric layer disposed between the first electrode and the second electrode, and a conductive interface layer disposed between the first electrode and the dielectric layer. The conductive interface layer includes a first conductive interface layer disposed between the first electrode and the dielectric layer, and a second conductive interface layer disposed between the first conductive interface layer and the dielectric layer. The dielectric layer includes a rutile-phase dielectric material. The first conductive interface layer includes a conductive metal oxide material having a stable crystal structure in a rutile phase. A conduction band offset between the second conductive interface layer and the dielectric layer is greater than a conduction band offset between the first conductive interface layer and the dielectric layer.

### CROSS-REFERENCE TO RELATED APPLICATIONS

This application is based on and claims priority under 35 U.S.C. § 119 to Korean Patent Application No. 10-2023-0170036, filed on Nov. 29, 2023, Korean Patent Application No. 10-2024-0026040, filed on Feb. 22, 2024, and Korean Patent Application No. 10-2024-0059420, filed on May 3, 2024, in the Korean Intellectual Property Office, the disclosures of which are incorporated by reference herein in their entirety.

### BACKGROUND

### 1. Field

The disclosure relates to capacitors and electronic devices including the same.

### 2. Description of the Related Art

As the degree of integration of electronic devices (such as memories) increases electronic elements in the electronic devices are becoming more miniaturized. However, because a capacitance of a capacitor is proportional to the area of the capacitor, the capacitance may decrease as the capacitor is miniaturized. Therefore, in order to compensate for the decrease in size of a capacitor and secure a desired capacitance, studies have been conducted into a method of further increasing a dielectric constant of a dielectric layer. In addition, studies have been conducted on a method of suppressing an increase in a leakage current due to miniaturization of capacitors.

### SUMMARY

Provided are capacitors including a dielectric layer including a high-k dielectric material and electronic devices including the same.

Provided are capacitors with improved leakage current characteristics and electronic devices including the same.

Additional aspects will be set forth in part in the description which follows and, in part, will be apparent from the description, or may be learned by practice of the presented embodiments of the disclosure.

According to an aspect of the disclosure, a capacitor includes a first electrode; a second electrode facing the first electrode; a dielectric layer between the first electrode and the second electrode, the dielectric layer including a rutile-phase dielectric material; and a conductive interface layer between the first electrode and the dielectric layer, the conductive interface layer comprising a first conductive interface layer between the first electrode and the dielectric layer and including a conductive metal oxide material having a stable crystal structure in a rutile phase, and a second conductive interface layer between the first conductive interface layer and the dielectric layer, wherein a conduction band offset between the second conductive interface layer and the dielectric layer is greater than a conduction band offset between the first conductive interface layer and the dielectric layer.

For example, the first conductive interface layer may include molybdenum oxide (MoO₂) doped with tin (Sn).

A concentration of the Sn in the first conductive interface layer may be within a range of about 0.1 at % to about 5.0 at %

A concentration of the Sn in the first conductive interface layer may be within a range of about 0.1 at % to about 3.0 at %.

The first conductive interface layer may have a thickness within a range of about 0.3 nm to about 4 nm.

The second conductive interface layer may include a second conductive metal oxide material having a stable crystal structure in a rutile phase.

The second conductive interface layer may include tin oxide (SnO₂), germanium oxide (GeO₂), or a mixture of tin oxide and germanium oxide ((SnₓGe₁₋ₓ)O₂, 0<x<1).

The second conductive interface layer may have a thickness within a range of about 0.3 nm to about 1 nm.

The dielectric layer may include rutile-phase titanium oxide (TiO₂).

The dielectric layer may include at least of gallium (Ga), aluminum (Al), lanthanum (La), boron (B), indium (In), scandium (Sc), or yttrium (Y) as a dopant.

A dopant doping concentration in the dielectric layer may be within a range of about 0 at % to about 20 at %.

The dielectric layer may have a thickness within a range of about 3 nm to about 7 nm.

The first electrode may include at least one of titanium nitride (TiN), vanadium nitride (VN), niobium nitride (NbN), tantalum nitride (TaN), molybdenum nitride (MoN), cobalt nitride (CoN), or a combination thereof.

The first electrode may have a thickness within a range of about 5 nm to about 10 nm.

According to another aspect of the disclosure, a method of manufacturing a capacitor includes forming a first material layer on an upper surface of a first electrode, the first material layer including amorphous molybdenum oxide (MoOₓ), forming a second material layer on an upper surface of the first material layer, the second material layer including tin oxide (SnO₂), forming a first conductive interface layer including molybdenum oxide (MoO₂) doped with tin (Sn) by crystallizing the amorphous molybdenum oxide through a heat treatment, forming a second conductive interface layer on the first conductive interface layer, the second conductive interface layer including tin oxide (SnO₂), germanium oxide (GeO₂), or a mixture of tin oxide and germanium oxide ((SnₓGe₁₋ₓ)O₂, 0<x<1), forming a dielectric layer on the second conductive interface layer, and forming a second electrode on the dielectric layer.

According to another aspect of the disclosure, an electronic device includes a transistor, and a capacitor electrically connected to the transistor, wherein the capacitor includes a first electrode, a second electrode facing the first electrode, a dielectric layer between the first electrode and the second electrode and including a rutile-phase dielectric material, and a conductive interface layer disposed between the first electrode and the dielectric layer, the conductive interface layer including a first conductive interface layer including a conductive metal oxide material having a stable crystal structure in a rutile phase between the first electrode and the dielectric layer, and a second conductive interface layer between the first conductive interface layer and the dielectric layer, wherein a conduction band offset between the second conductive interface layer and the dielectric layer is greater than a conduction band offset between the first conductive interface layer and the dielectric layer.

According to another aspect of the disclosure, an electronic device includes a transistor, and a capacitor electrically connected to the transistor, wherein the capacitor includes two electrodes facing each other, a dielectric layer between the two electrodes, the dielectric layer including titanium oxide (TiO₂), a molybdenum oxide (MoO₂) layer doped with tin (Sn) between one of the two electrodes and the dielectric layer, and an interface layer including tin (Sn) oxide and/or germanium (Ge) oxide between the molybdenum oxide (MoO₂) layer doped with Sn and the dielectric layer.

A concentration of the Sn in the molybdenum oxide (MoO₂) layer doped with Sn may be within a range of about 0.1 at % to about 5.0 at %.

A concentration of the Sn in the molybdenum oxide (MoO₂) layer doped with Sn may be within a range of about 0.1 at % to about 3.0 at %.

A concentration of the Sn in the molybdenum oxide (MoO₂) layer doped with Sn may be within a range of about 0.5 at % to about 3.0 at %.

For example, the TiO₂ included in the dielectric layer may be in a rutile phase and one of the two electrodes may include titanium nitride (TiN).

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a schematic structure of a capacitor according to at least one embodiment;

FIG. 2 is a schematic energy band diagram illustrating a conduction band offset (CBO) between a second conductive interface layer and a dielectric layer of the capacitor illustrated in FIG. 1;

FIGS. 3A to 3D are cross-sectional views schematically illustrating a process of forming a conductive interface layer of the capacitor illustrated in FIG. 1;

FIG. 4 shows a high resolution-transmission electron microscopy (HR-TEM) photograph of an actually manufactured conductive interface layer according to an example;

FIG. 5 shows an HR-TEM photograph of an actually manufactured conductive interface layer according to a comparative example;

FIGS. 6A to 6D are photographs of a surface of a first conductive interface layer, showing a change in surface roughness of a conductive interface layer according to a change in content of tin (Sn) in the first conductive interface layer;

FIG. 7 is a graph showing an example of an ultraviolet (UV) photoelectron spectroscopy (UPS) spectrum obtained through UPS measurement for a first conductive interface layer;

FIG. 8 is a table showing a change in a work function of a first conductive interface layer according to a change in content of Sn in the first conductive interface layer, which is obtained through density functional theory (DFT) simulation;

FIG. 9 is a graph showing a comparison of leakage current characteristics between a capacitor including a conductive interface layer according to an example and a capacitor including a conductive interface layer according to a comparative example;

FIG. 10 is a graph showing a comparison of leakage current characteristics between capacitors according to a content of Sn in a first conductive interface layer;

FIG. 11 is a circuit diagram for describing a schematic circuit configuration and operation of an electronic device employing a capacitor, according to embodiments;

FIG. 12 is a schematic diagram illustrating an electronic device according to at least one embodiment;

FIG. 13 is a schematic diagram illustrating an electronic device according to another embodiment;

FIG. 14 is a plan view illustrating an electronic device according to another embodiment;

FIG. 15 is a cross-sectional view of the electronic device of FIG. 13 taken along line A-A′ of FIG. 13;

FIG. 16 is a cross-sectional view illustrating an electronic device according to another embodiment; and

FIGS. 17 and 18 are conceptual diagrams schematically illustrating device architectures applicable to a device, according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. Additionally, whenever a range of values is enumerated, the range includes all values within the range as if recorded explicitly clearly, and may further include the boundaries of the range. Accordingly, the range of “X” to “Y” includes all values between X and Y, including X and Y. Further, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry.

Hereinafter, a capacitor and an electronic device including the same will be described in detail with reference to the accompanying drawings. In the following drawings, the same reference numerals denote the same elements, and the size of each element in the drawings may be exaggerated for clarity and convenience of explanation. In addition, embodiments described herein are merely examples, and various modifications may be made thereto from these embodiments.

Hereinafter, the terms “above,” “on,” “below,” or “under” may include not only those that are directly above, below, left, or right in a contact manner, but also those that are above, below, left, or right in a non-contact manner. For example, it will be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. The singular forms “a,” “an,” and “the” as used herein are intended to include the plural forms as well unless the context clearly indicates otherwise. It will be understood that the terms “comprise,” “include,” or “have” as used herein specify the presence of stated elements, but do not preclude the presence or addition of one or more other elements.

The use of the term “the” and similar demonstratives may correspond to both the singular and the plural. Operations constituting methods may be performed in any suitable order unless otherwise indicated herein or otherwise clearly contradicted by context, and are not necessarily limited to the stated order.

Also, the terms such as “unit” and “module” described in the specification mean units that process at least one function or operation, and may be implemented as processing circuitry including hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc., and/or electronic circuits including said components.

Connecting lines or connecting members illustrated in the drawings are intended to represent exemplary functional relationships and/or physical or logical connections between the various elements. It should be noted that many alternative or additional functional relationships, physical connections or logical connections may be present in a practical device.

The use of all illustrations or illustrative terms in the embodiments is simply to describe the technical ideas in detail, and the scope of the disclosure is not limited by the illustrations or illustrative terms unless they are limited by claims.

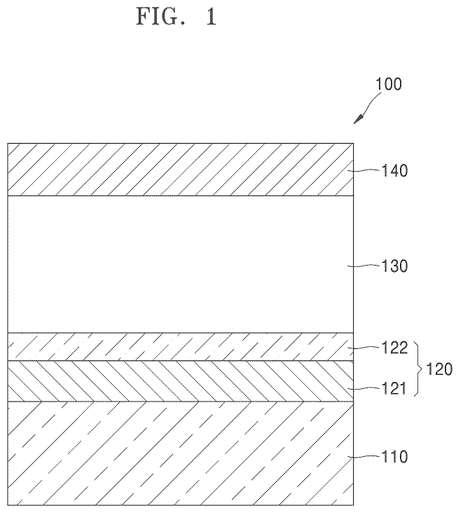

FIG. 1 is a cross-sectional view illustrating a schematic structure of a capacitor 100 according to at least one embodiment. Referring to FIG. 1, the capacitor 100 may include a first electrode 110, a second electrode 140 disposed to face the first electrode 110, a dielectric layer 130 disposed between the first electrode 110 and the second electrode 140, and a conductive interface layer 120 disposed between the first electrode 110 and the dielectric layer 130. That is, the dielectric layer 130 may be disposed between the two electrodes 110 and 140 facing each other. In a process of manufacturing the capacitor 100, the conductive interface layer 120 may be formed on an upper surface of the first electrode 110, the dielectric layer 130 may be formed on an upper surface of the conductive interface layer 120, and the second electrode 140 may be formed on an upper surface of the dielectric layer 130.

The dielectric layer 130 may include a rutile-phase dielectric material. For example, the dielectric layer 130 may include rutile-phase titanium oxide (TiO₂). Titanium oxide has a different dielectric constant depending on a phase thereof. While anatase-phase titanium oxide has a dielectric constant of about 40, rutile-phase titanium oxide may have a great dielectric constant of about 80 to about 170 depending on a growth direction thereof. Accordingly, the dielectric layer 130 including rutile-phase titanium oxide may have a dielectric constant of about 80 to about 170.

The dielectric layer 130 may include only titanium oxide, or may further include a dopant with titanium oxide. In at least one example, the dopant might be a p-type dopant with p-type electrical characteristics. For example, the dielectric layer 130 may include titanium oxide doped with at least one dopant selected from gallium (Ga), aluminum (Al), lanthanum (La), boron (B), indium (In), scandium (Sc), yttrium (Y), and/or the like. A dopant doping concentration in the dielectric layer 130 may be, for example, about 0 at % to about 20 at %. The rutile-phase titanium oxide has a high dielectric constant, but a leakage current may occur because the rutile-phase titanium oxide has n-type electrical characteristics. Because the dopant doped into the dielectric layer 130 has p-type electrical characteristics, leakage current characteristics of the dielectric layer 130 may be improved.

According to at least one embodiment, because the dielectric layer 130 has a high dielectric constant, the thickness of the dielectric layer 130 may be reduced and the capacitor 100 may be further miniaturized. For example, the dielectric layer 130 may have a thickness of about 3 nm to about 7 nm.

The first electrode 110 may include a conductive metal nitride. In particular, the first electrode 110 may include a metal nitride having thermal stability such that the metal nitride is not easily reduced to metal during a heat treatment process (for example at 400° C. or more; and/or between about 450° C. to about 600° C. as described below). For example, the first electrode 110 may include at least one conductive metal nitride selected from titanium nitride (TiN), vanadium nitride (VN), niobium nitride (NbN), tantalum nitride (TaN), molybdenum nitride (MoN), cobalt nitride (CoN), a combination thereof, and/or the like. The first electrode 110 may have a thickness of about 5 nm to about 10 nm.

The second electrode 140 includes a conductive material. The conductive material of the second electrode 140 is not particularly limited. For example, the second electrode 140 may have a single-layer structure or a multilayer structure including metal, metal nitride, metal oxide, a combination thereof, and/or the like. The second electrode 140 may include, for example, TiN, MoN, CoN, TaN, tungsten (W), ruthenium (Ru), ruthenium oxide (RuO₂), strontium-ruthenium oxide (SRO or SrRuO₃), iridium (Ir), iridium oxide (IrO₂), platinum (Pt), platinum oxide (PtO), barium-strontium-ruthenium oxide (BSRO or (Ba,Sr)RuO₃), calcium-ruthenium oxide (CRO or CaRuO₃), lanthanum-strontium-cobalt oxide (LSCO or (La,Sr)CoO₃), a combination thereof, and/or the like.

The conductive interface layer 120 may be configured to enable the rutile-phase dielectric layer 130 to be grown thereon, to stabilize the rutile-phase dielectric layer, and/or to reduce a leakage current. According to at least one embodiment, the conductive interface layer 120 may include a first conductive interface layer 121 disposed on the upper surface of the first electrode 110 and a second conductive interface layer 122 disposed on the upper surface of the first conductive interface layer 121. The dielectric layer 130 may be disposed on the upper surface of the second conductive interface layer 122. Therefore, the first conductive interface layer 121 may also be referred to as disposed between the first electrode 110 and the dielectric layer 130, and in particular, between the first electrode 110 and the second conductive interface layer 122, and the second conductive interface layer 122 may be referred to as disposed between the first conductive interface layer 121 and the dielectric layer 130.

The first conductive interface layer 121 may include a conductive metal oxide material having a stable crystal structure in the rutile phase such that the rutile-phase dielectric layer 130 may be grown on the conductive interface layer 120. In addition, the first conductive interface layer 121 may include a conductive metal oxide material having thermal stability such that the conductive metal oxide is not easily reduced to metal during a heat treatment process (for example at 400° C. or more; and/or between about 450° C. to about 600° C., as described below). The first conductive interface layer 121 may also include a conductive metal oxide material that has a sufficiently high work function while having little deterioration of film quality during a crystallization process. The first conductive interface layer 121 may include, for example, molybdenum oxide (MoO₂) doped with Sn. In at least one embodiment, the first conductive interface layer 121 may include both molybdenum oxide (MoO₂) and tin oxide (SnO₂). Accordingly, the first conductive interface layer 121 may also be referred to as a “molybdenum oxide (MoO₂) layer doped with Sn” that is disposed between one of the two electrodes 110 and 140, that is, the first electrode 110 and the dielectric layer 130.

Like the first conductive interface layer 121, the second conductive interface layer 122 may include a conductive metal oxide material having a stable crystal structure in a rutile phase. In addition, the second conductive interface layer 122 may include a conductive metal oxide material that has a sufficiently high conduction band offset (CBO) with the dielectric layer 130 so as to reduce a leakage current. For example, the material of the second conductive interface layer 122 may be selected so that the CBO between the second conductive interface layer 122 and the dielectric layer 130 is greater than the CBO between the first conductive interface layer 121 and the dielectric layer 130. In at least one embodiment, the second conductive interface layer 122 may include, for example, tin oxide (SnO₂), germanium oxide (GeO₂), or a mixture ((SnₓGe₁₋ₓ)O₂, 0<x<1) of tin oxide and germanium oxide. Accordingly, the second conductive interface layer 122 may also be referred to as an “interface layer including tin oxide and/or germanium oxide” that is disposed between the “molybdenum oxide (MoO₂) layer doped with Sn” and the dielectric layer 130.

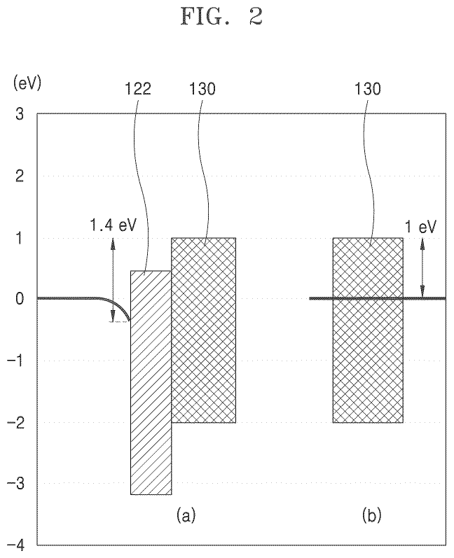

FIG. 2 is a schematic energy band diagram illustrating the CBO between the second conductive interface layer and the dielectric layer of the capacitor illustrated in FIG. 1. In FIG. 2, (a) illustrates an example of the CBO between the second conductive interface layer 122 and the dielectric layer 130, and (b) illustrates an example of the CBO between the first conductive interface layer 121 and the dielectric layer 130 for comparison. Referring to FIG. 2, the CBO between the second conductive interface layer 122 and the dielectric layer 130 may be more than about 1 eV. For example, the CBO between the second conductive interface layer 122 and the dielectric layer 130 may be about 1.4 eV, or about 1.4 eV to about 1.5 eV. On the other hand, the CBO between the first conductive interface layer 121 and the dielectric layer 130 may be about 1 eV, which is less than the CBO between the second conductive interface layer 122 and the dielectric layer 130.

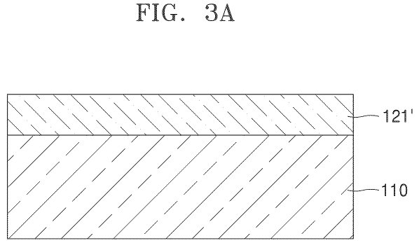

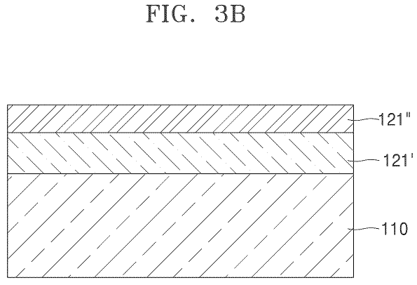

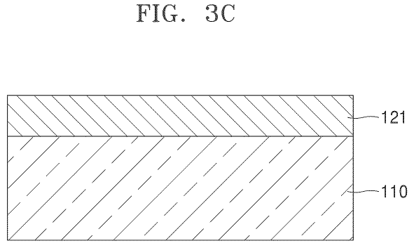

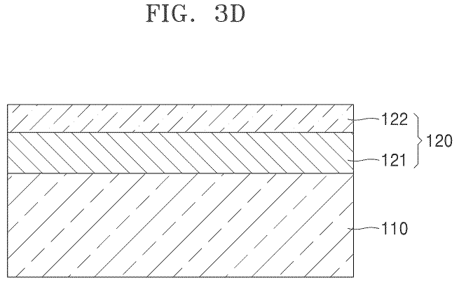

FIGS. 3A to 3D are cross-sectional views schematically illustrating a process of forming the conductive interface layer 120 of the capacitor 100 illustrated in FIG. 1.

Referring to FIG. 3A, a first material layer 121′ including amorphous molybdenum oxide (MoOₓ) may be formed on the upper surface of the first electrode 110. The first material layer 121′ may be formed through, for example, pulsed laser deposition (PLD) or atomic layer deposition (ALD). Alternatively, the first material layer 121′ may be formed through other deposition methods, such as chemical vapor deposition (CVD) or physical vapor deposition (PVD).

Referring to FIG. 3B, a second material layer 121″ including tin oxide (SnO₂) may be formed on the upper surface of the first material layer 121′. For example, the second material layer 121″ may be formed through ALD.

Referring to FIG. 3C, the first material layer 121′ may be crystallized through post metallization annealing (PMA). The PMA may include a heat treatment process, and may be performed at a temperature of, for example, about 450° C. to about 600° C. Thus, amorphous molybdenum oxide (MoOₓ) may be crystallized to form crystalline molybdenum oxide (MoO₂) in a rutile-phase. In this process, tin oxide (SnO₂) of the second material layer 121″ on the first material layer 121′ may be mixed in the crystal structure of crystalline molybdenum oxide (MoO₂). Then, the first conductive interface layer 121 including crystalline molybdenum oxide (MoO₂) doped with Sn and/or including both crystalline molybdenum oxide (MoO₂) and crystalline tin oxide (SnO₂) may be formed on the upper surface of the first electrode 110. In at least some embodiments, the first conductive interface layer 121 may formed to have a thickness of about 0.3 nm to about 4 nm, and/or about 0.3 nm to about 3 nm.

Referring to FIG. 3D, a second conductive interface layer 122 may be formed on the first conductive interface layer 121. For example, the second conductive interface layer 122 may be formed on the first conductive interface layer 121 by growing crystalline tin oxide (SnO₂), crystalline germanium oxide (GeO₂), and/or a mixture ((SnₓGe₁₋ₓ)O₂, 0<x<1) of crystalline tin oxide and crystalline germanium oxide on the first conductive interface layer 121 through ALD. In this manner, the conductive interface layer 120 may be completed. In at least some embodiments, the second conductive interface layer 122 may formed to have a thickness of about 0.3 nm to about 1 nm, or about 0.3 nm to about 0.6 nm.

After the process of FIG. 3D, a dielectric layer 130 may be formed on the conductive interface layer 120, particularly the second conductive interface layer 122, and a second electrode 140 may be formed on the dielectric layer 130. In this manner, the capacitor 100 may be manufactured. For example, the dielectric layer 130 may be formed by depositing titanium oxide (TiO₂) through ALD. The dielectric layer 130 including rutile-phase titanium oxide (TiO₂) may be implemented by depositing titanium oxide (TiO₂) through ALD on the conductive interface layer 120 having a stable crystal structure in a rutile phase.

According to at least one embodiment, in the process of forming the first conductive interface layer 121, film quality deterioration of crystallized molybdenum oxide (MoO₂) may be alleviated by the doping with Sn when crystallizing the amorphous molybdenum oxide (MoOₓ). Accordingly, the conductive interface layer 120 may have a relatively uniform thickness of about 4 nm or less, and the surface roughness of the conductive interface layer 120 may be relatively small. In these cases, the dielectric layer 130 may be formed homogeneously on the conductive interface layer 120; for example, the homogenous surface of the conductive interface layer 120 may reduce/or prevent the formation of lattice defects in the dielectric layer 130 and, therefore, a leakage current may be lowered.

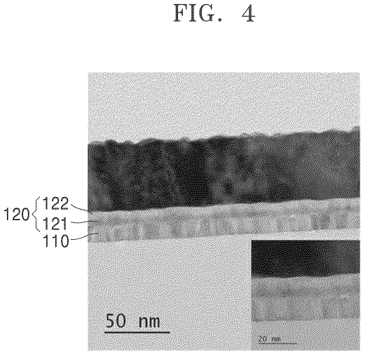

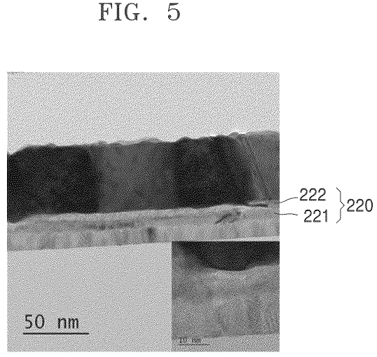

FIG. 4 shows a high resolution-transmission electron microscopy (HR-TEM) photograph of an actually manufactured conductive interface layer 120 according to an example, and FIG. 5 shows an HR-TEM photograph of an actually manufactured conductive interface layer 220 according to a comparative example. In the conductive interface layer 220 of FIG. 5 according to the comparative example, a first conductive interface layer 221 includes only Sn-undoped crystalline molybdenum oxide (MoO₂) (i.e., MoS₂ without Sn). A portion of the conductive interface layer is enlarged at the bottom right of FIGS. 4 and 5. Referring to FIG. 4, it may be confirmed that the thicknesses of a first conductive interface layer 121 and a second conductive interface layer 122 in the conductive interface layer 120 according to the example are relatively uniform. On the other hand, referring to FIG. 5, the thicknesses of the first conductive interface layer 221 and a second conductive interface layer 222 in the conductive interface layer 220 according to the comparative example are not uniform. This is a result of film quality deterioration of molybdenum oxide (MoO₂) during a process of crystallizing molybdenum oxide (MoO₂) due to a large ionic radius of molybdenum (Mo). In the case of the conductive interface layer 120 according to the example, film quality deterioration of molybdenum oxide (MoO₂) may be alleviated due to Sn doped into molybdenum oxide (MoO₂).

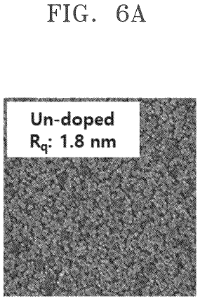

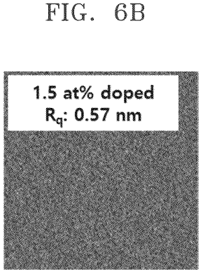

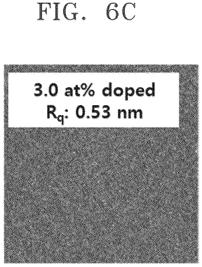

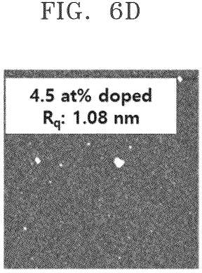

FIGS. 6A to 6D are photographs of the surface of the first conductive interface layer, showing a change in surface roughness of the conductive interface layer according to a change in content of Sn in the first conductive interface layer. Referring to FIG. 6A, the root mean square (RMS) surface roughness of the first conductive interface layer 221 according to the comparative example, which is undoped with Sn, is about 1.8 nm. Referring to FIGS. 6B and 6C, the RMS surface roughness of the first conductive interface layer 121 according to an example, which is doped with Sn at a concentration of about 1.5 at %, is about 0.57 nm, and the RMS surface roughness of the first conductive interface layer 121 according to an example, which is doped with Sn at a concentration of about 3.0 at %, is about 0.53 nm. Accordingly, it may be confirmed that the surface roughness of the first conductive interface layer 121 according to the examples are significantly lower than the surface roughness of the conductive interface layer 221 according to the comparative example. In addition, it may be confirmed that, as the Sn doping concentration in the first conductive interface layer 121 increases from about 1.5 at % to about 3.0 at %, the surface roughness of the first conductive interface layer 121 becomes lower.

Referring to FIG. 6D, the RMS surface roughness of the first conductive interface layer 121 according to the example, which is doped with Sn at a concentration of about 4.5 at %, is about 1.08 nm. It may be confirmed that, as the Sn doping concentration in the first conductive interface layer 121 increases from about 3.0 at % to about 4.5 at %, the surface roughness of the first conductive interface layer 121 increases again. However, even when the Sn doping concentration in the first conductive interface layer 121 is about 4.5 at %, the surface roughness of the first conductive interface layer 121 is significantly lower than the surface roughness of the first conductive interface layer 221 according to the comparative example, which is undoped with Sn.

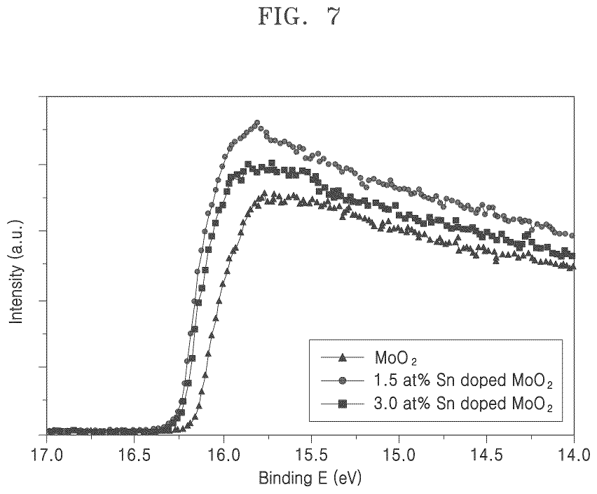

FIG. 7 is a graph showing an example of an ultraviolet (UV) photoelectron spectroscopy (UPS) spectrum obtained through UPS measurement for the first conductive interface layer. The UPS spectrum illustrated in FIG. 7 is obtained by forming the 3-nm-thick first conductive interface layer on the 10-nm-thick first electrode 110 formed of titanium nitride (TiN) and irradiating the first conductive interface layer with UV light of about 21.22 eV in a vertical direction. In the graph of FIG. 7, the horizontal axis represents binding energy and the vertical axis represents the intensity or kinetic energy of electrons ejected by a photoelectric effect. A work function of a sample may be obtained from a difference between 21.22 eV and an X intercept value of a differentiated value for the UPS spectrum graph illustrated in FIG. 7.

Referring to FIG. 7, the work function of the first conductive interface layer 221 according to the comparative example, which is undoped with Sn, is about 5.12 eV. In addition, the work function of the first conductive interface layer 121 according to the example, which is doped with Sn at a concentration of about 1.5 at %, is about 5.02 eV, and the work function of the first conductive interface layer 121 according to the example, which is doped with Sn at a concentration of about 3.0 at %, is about 5.03 eV. Therefore, it may be confirmed that the work function of the first conductive interface layer 121 according to the examples, which are doped with Sn, is slightly lower than the work function of the first conductive interface layer 221 according to the comparative example, which is undoped with Sn.

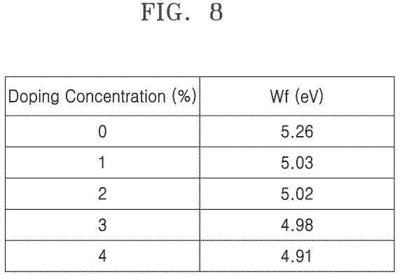

FIG. 8 is a table showing a change in work function of the first conductive interface layer according to a change in content of Sn in the first conductive interface layer obtained through density functional theory (DFT) simulation. Referring to the simulation result of FIG. 8, the work function of the first conductive interface layer 221 according to the comparative example, which is undoped with Sn, is the highest. In the case of the first conductive interface layer 121 according to the example, the work function gradually decreases as the content of Sn increases. The simulation result may roughly match the UPS measurement result illustrated in FIG. 7.

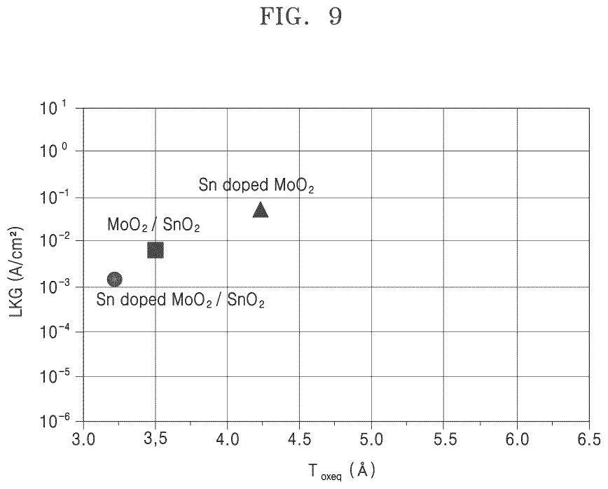

FIG. 9 is a graph showing a comparison of leakage current characteristics between the capacitor 100 including the conductive interface layer 120 according to the example and the capacitor including the conductive interface layer according to the comparative example. Referring to FIG. 9, a leakage current of a capacitor according to Comparative Example 1 (▴), which includes only the first conductive interface layer formed of MoO₂ doped with Sn and does not include the second conductive interface layer, is the greatest, and the equivalent oxide thickness thereof is also the greatest. A leakage current and an equivalent oxide thickness of a capacitor according to Comparative Example 2 (▪), which includes the first conductive interface layer formed of MoO₂ undoped with Sn and the second conductive interface layer formed of SnO₂, may be respectively smaller than the leakage current and the equivalent oxide thickness of the capacitor according to Comparative Example 1. In addition, it may be confirmed that a leakage current and an equivalent oxide thickness of the capacitor 100 according to the example (●), which includes both the first conductive interface layer 121 formed of MoO₂ doped with Sn and the second conductive interface layer 122 formed of SnO₂, are the smallest.

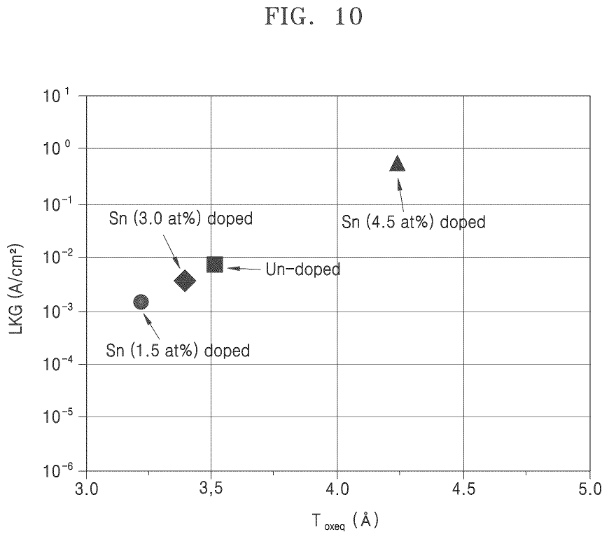

FIG. 10 is a graph showing a comparison of leakage current characteristics between the capacitors 100 according to the content of Sn in the first conductive interface layer. Referring to FIG. 10, when the Sn doping concentration in the first conductive interface layer 121 is about 1.5 at % (●), the leakage current and the equivalent oxide thickness of the capacitor 100 are the smallest. The leakage current and the equivalent oxide thickness of the capacitor 100 (♦) in which the Sn doping concentration in the first conductive interface layer 121 is about 3.0 at % are slightly greater than the leakage current and the equivalent oxide thickness of the capacitor 100 in which the Sn doping concentration in the first conductive interface layer 121 is about 1.5 at %, but are smaller than the leakage current and the equivalent oxide thickness of the capacitor according to the comparative example (▪). On the other hand, the leakage current and the equivalent oxide thickness of the capacitor 100 (▴) in which the Sn doping concentration in the first conductive interface layer 121 is about 4.5 at % are greater than the leakage current and the equivalent oxide thickness of the capacitor according to the comparative example.

When comprehensively considering a change in various characteristics according to a change in the Sn doping concentration in the first conductive interface layer 121 observed through FIGS. 6A to 6D and 7 to 10, the Sn doping concentration in the first conductive interface layer 121 may be about 0.1 at % to about 5.0 at %. Alternatively, the Sn doping concentration in the first conductive interface layer 121 may be about 0.1 at % to about 4.0 at %, about 0.1 at % to about 3.0 at %, and/or about 0.5 at % to about 3.0 at %.

As described above, in the case of the capacitor 100 according to the example, the dielectric layer 130 including a rutile-phase dielectric material may be formed through ALD using the first conductive interface layer 121 doped with Sn. Accordingly, the disclosed capacitors 100 may be miniaturized and have high capacitance. In addition, because the material of the first electrode 110 is chemically stable, the material of the first electrode 110 is unlikely to be reduced to a metal in a subsequent process. In addition, the leakage current may be decreased by using the second conductive interface layer 122 having a sufficiently large CBO with the dielectric layer 130.

The capacitor may be employed in various electronic devices. The capacitor may be used as a dynamic random access memory (DRAM) together with a transistor. In addition, the capacitor may be used for a portion of an electronic circuit constituting an electronic device together with other circuit elements.

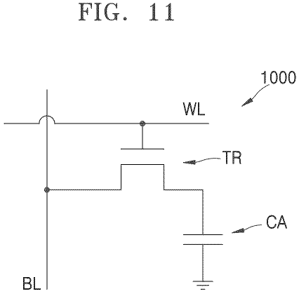

FIG. 11 is a circuit diagram for describing a schematic circuit configuration and operation of an electronic device 1000 employing a capacitor, according to some embodiments.

The circuit diagram of the electronic device 1000 is for one cell of a DRAM, and the electronic device 1000 includes one transistor TR, one capacitor CA, a word line WL, and a bit line BL. The capacitor CA may be the capacitors 100 described with reference to FIGS. 1 to 10.

A method of writing data to the DRAM is as follows. After a gate voltage (high) for turning the transistor TR on (“ON” state) is applied to a gate electrode through the word line WL, VDD (hereinafter, a high voltage) or 0 (hereinafter, a low voltage), which is a data voltage value to be input, is applied to the bit line BL. When a high voltage is applied to the word line WL and the bit line BL, the capacitor CA is charged, that is, data “1” is written. When a high voltage is applied to the word line WL and a low voltage is applied to the bit line BL, the capacitor CA is discharged, that is, data “0” is written.

Upon reading data, a high voltage is applied to the word line WL to turn on the transistor TR of the DRAM, and a voltage of VDD/2 is applied to the bit line BL. When the data of the DRAM is “1,” that is, when the voltage of the capacitor CA is VDD, charges stored in the capacitor CA slowly move to the bit line BL and the voltage of the bit line BL becomes slightly higher than VDD/2. In contrast, when the data of the capacitor CA is “0,” charges of the bit line BL move to the capacitor CA and the voltage of the bit line BL becomes slightly lower than VDD/2. A sense amplifier may sense and amplify the potential difference of the bit line and determine whether the data is “0” or “1.”

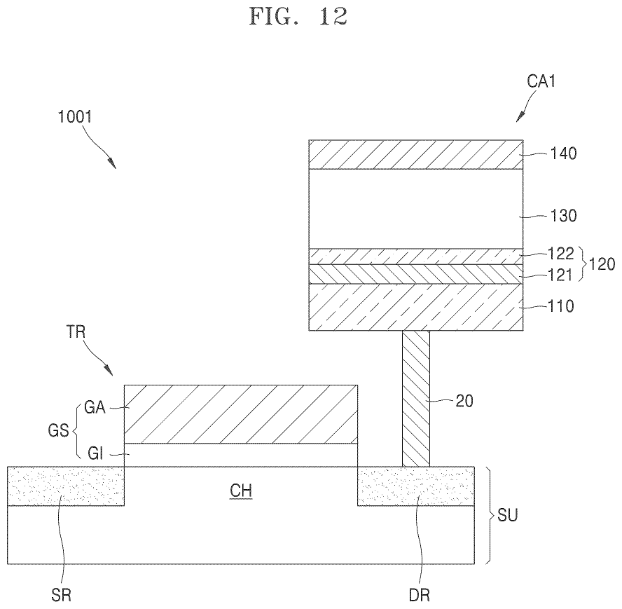

FIG. 12 is a schematic diagram illustrating an electronic device 1001 according to at least one embodiment.

Referring to FIG. 12, the electronic device 1001 may include a structure in which a capacitor CA1 and a transistor TR are electrically connected to each other through a contact 20. The capacitor CA1 may include a first electrode 110, a second electrode 140, a dielectric layer 130 between the first electrode 110 and the second electrode 140, and a conductive interface layer 120 between the first electrode 110 and the dielectric layer 130. The capacitor CA1 may be the capacitors 100 described with reference to FIGS. 1 to 10. Because this has been described above, detailed descriptions thereof are omitted.

The transistor TR may be a field effect transistor. The transistor TR includes a semiconductor substrate SU and a gate stack GS. The semiconductor substrate SU may include a source region SR, a drain region DR, and a channel region CH. The gate stack GS is disposed on the semiconductor substrate SU, faces the channel region CH, and includes a gate insulating layer GI and a gate electrode GA.

The channel region CH is a region between the source region SR and the drain region DR and is electrically connected to the source region SR and the drain region DR. The source region SR may be electrically connected to or in contact with one end of the channel region CH, and the drain region DR may be electrically connected to or in contact with the other end of the channel region CH. The channel region CH may be defined as a substrate region between the source region SR and the drain region DR in the semiconductor substrate SU.

The semiconductor substrate SU may include a semiconductor material. The semiconductor substrate SU may include, for example, an elemental and/or a compound semiconductor material, such as silicon (Si), germanium (Ge), silicon germanium (SiGe), silicon carbide (SiC), gallium arsenide (GaAs), indium arsenide (InAs), indium phosphide (InP), and/or the like. In addition, the semiconductor substrate SU may include a silicon on insulator (SOI) substrate.

The source region SR, the drain region DR, and the channel region CH may each independently be formed by implanting impurities into different regions of the semiconductor substrate SU. In this case, the source region SR, the channel region CH, and the drain region DR may each include a substrate material as a base material. The source region SR and the drain region DR may each include a conductive material. In this case, the source region SR and the drain region DR may each include, for example, a metal, a metal compound, or a conductive polymer.

The channel region CH may also be implemented as a separate material layer (thin film), unlike the illustration thereof. In these cases, for example, the channel region CH may include at least one of Si, Ge, SiGe, a Group III-V semiconductor, an oxide semiconductor, a nitride semiconductor, an oxynitride semiconductor, a two-dimensional (2D) material, a quantum dot (QD), and an organic semiconductor. For example, the oxide semiconductor may include InGaZnO and/or the like, the 2D material may include transition metal dichalcogenide (TMD) or graphene, and the QD may include a colloidal QD or a nanocrystal structure.

The gate electrode GA may be disposed on the semiconductor substrate SU and may face the channel region CH while being apart from the semiconductor substrate SU. The gate electrode GA may include at least one of a metal, a metal nitride, a metal carbide, and polysilicon. For example, the metal may include at least one of aluminum (Al), tungsten (W), molybdenum (Mo), titanium (Ti), and tantalum (Ta), and the metal nitride may include at least one of titanium nitride (TiN) and tantalum nitride (TaN). The metal carbide may include at least one of aluminum-doped (or aluminum-containing) metal carbide and silicon-doped (or silicon-containing) metal carbide. Specific examples of the metal carbide may include TiAlC, TaAlC, TiSiC, or TaSiC.

In at least one embodiment, the gate electrode GA may have a structure in which a plurality of materials are stacked. For example, the gate electrode GA may have a structure (e.g., TiN/Al) in which a metal nitride layer and a metal layer are stacked, or a structure (e.g., TiN/TiAlC/W) in which a metal nitride layer, a metal carbide layer, and a metal layer are stacked. However, the materials described above are only an example.

The gate insulating layer GI may be further arranged between the semiconductor substrate SU and the gate electrode GA. The gate insulating layer GI may include a paraelectric material or a high-k dielectric material, and may have a dielectric constant of about 20 to about 70.

The gate insulating layer GI may include silicon oxide, silicon nitride, aluminum oxide, hafnium oxide, zirconium oxide, or the like, or may include a 2D insulator, such as hexagonal boron nitride (h-BN). For example, the gate insulating layer GI may include silicon oxide (SiO₂), silicon nitride (SiNₓ), or the like, and may include hafnium oxide (HfO₂), hafnium silicon oxide (HfSiO₄), lanthanum oxide (La₂O₃), lanthanum aluminum oxide (LaAlO₃), zirconium oxide (ZrO₂), hafnium zirconium oxide (HfZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), lead scandium tantalum oxide (PbSc_{0.5}Ta_{0.5}O₃), lead zinc niobate (PbZnNbO₃), and/or the like. In addition, the gate insulating layer GI may include metal nitride oxide (e.g., aluminum oxynitride (AlON), zirconium oxynitride (ZrON), hafnium oxynitride (HfON), lanthanum oxynitride (LaON), yttrium oxynitride (YON), etc.), silicate (e.g., ZrSiON, HfSiON, YSiON, LaSiON, etc.), and/or aluminate (e.g., ZrAlON, HfAlON, etc.). In addition, the gate insulating layer GI may constitute a gate stack together with the gate electrode GA.

One of the first electrode 110 and the second electrode 140 of the capacitor CA1 and one of the source region SR and the drain region DR of the transistor TR may be electrically connected to each other, e.g., through the contact 20. The contact 20 may include an appropriate conductive material, for example, tungsten, copper, aluminum, or polysilicon.

The arrangement of the capacitor CA1 and the transistor TR may be variously modified. For example, the capacitor CA1 may be disposed on the semiconductor substrate SU, and/or may be buried in the semiconductor substrate SU.

FIG. 12 illustrates that the electronic device 1001 includes one capacitor CA1 and one transistor TR, but this is only an example, and the electronic device 1001 may include a plurality of capacitors and a plurality of transistors.

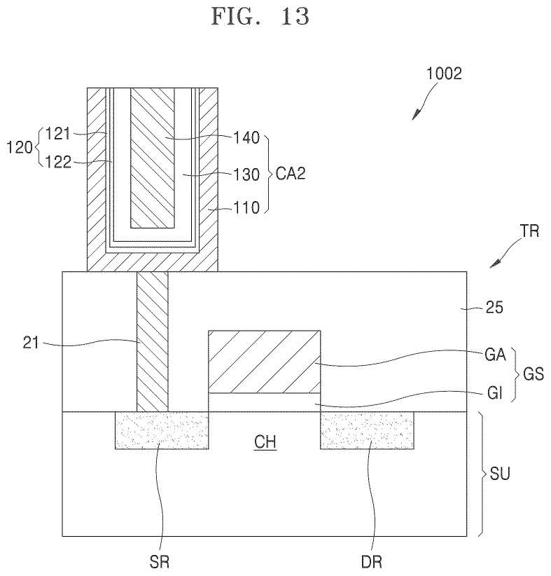

FIG. 13 is a schematic diagram illustrating an electronic device 1002 according to another embodiment.

Referring to FIG. 13, the electronic device 1002 may include a structure in which a capacitor CA2 and a transistor TR are electrically connected to each other, e.g., through a contact 21. The transistor TR includes a semiconductor substrate SU and a gate stack GS. The semiconductor substrate SU includes a source region SR, a drain region DR, and a channel region CH. The gate stack GS is disposed on the semiconductor substrate SU, faces the channel region CH, and includes a gate insulating layer GI and a gate electrode GA.

An interlayer insulating layer 25 may be disposed on the semiconductor substrate SU to cover the gate stack GS. The interlayer insulating layer 25 may include an insulating material. For example, the interlayer insulating layer 25 may include Si oxide (e.g., SiO₂), Al oxide (e.g., Al₂O₃), or a high-k material (e.g., HfO₂). The contact 21 passes through the interlayer insulating layer 25 to electrically connect the transistor TR to the capacitor CA2.

The capacitor CA2 includes a first electrode 110, a second electrode 140, a dielectric layer 130 between the first electrode 110 and the second electrode 140, and a conductive interface layer 120 between the first electrode 110 and the dielectric layer 130. The first electrode 110 and the second electrode 140 are provided in a shape capable of maximizing the contact area with the dielectric layer 130, and the material of the capacitor CA2 is substantially the same as the material of the capacitors 100 described with reference to FIGS. 1 to 10.

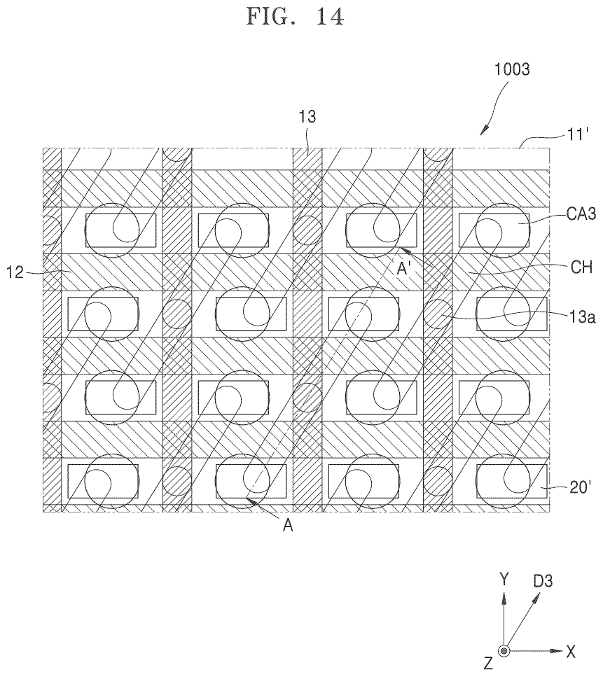

FIG. 14 is a plan view illustrating an electronic device 1003 according to another embodiment.

Referring to FIG. 14, the electronic device 1003 may include a structure in which a plurality of capacitors and a plurality of field effect transistors are repeatedly arranged. The electronic device 1003 may include a field effect transistor, a contact structure 20′, and a capacitor CA3. The field effect transistor includes a semiconductor substrate 11′ including a source, a drain, and a channel, and a gate stack 12. The contact structure 20′ is disposed on the semiconductor substrate 11′ so as not to overlap the gate stack 12. The capacitor CA3 is disposed on the contact structure 20′. The electronic device 1003 may further include a bit line structure 13 electrically connecting the field effect transistors to each other.

Although FIG. 14 illustrates that both the contact structure 20′ and the capacitor CA3 are repeatedly arranged in the X and Y directions, the disclosure is not limited thereto. For example, the contact structure 20′ may be arranged in the X and Y directions, and the capacitor CA3 may be arranged in a hexagonal shape, such as a honeycomb structure.

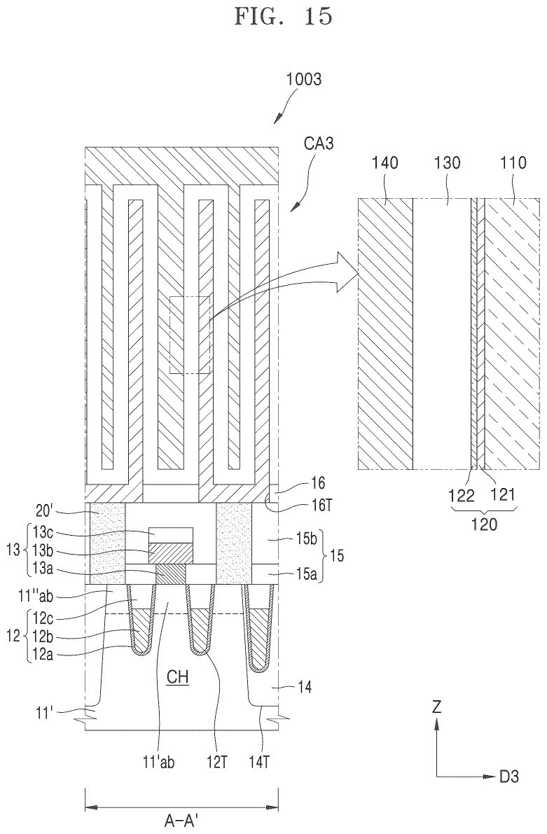

FIG. 15 is a cross-sectional view of the electronic device 1003 taken along line A-A′ of FIG. 14.

Referring to FIG. 15, the semiconductor substrate 11′ may have a shallow trench isolation (STI) structure including a device isolation layer 14. The device isolation layer 14 may be a single layer including one type of insulating layer, or multiple layers including a combination of two or more types of insulating layers. The device isolation layer 14 may include a device isolation trench 14T in the semiconductor substrate 11′, and the device isolation trench 14T may be filled with an insulating material. The insulating material may include at least one of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and/or tonen silazene (TOSZ), but the disclosure is not limited thereto.

The semiconductor substrate 11′ may further include a channel region CH defined by the device isolation layer 14, and a gate line trench 12T parallel to the upper surface of the semiconductor substrate 11′ and extending in the X direction. The channel region CH may have a relatively long island shape having a minor axis and a major axis. The major axis of the channel region CH may be arranged in a D3 direction parallel to the upper surface of the semiconductor substrate 11′, as illustrated in FIG. 14.

The gate line trench 12T may be arranged to cross the channel region CH at a certain depth from the upper surface of the semiconductor substrate 11′, or may be arranged inside the channel region CH. The gate line trench 12T may also be arranged inside the device isolation trench 14T. The gate line trench 12T inside the device isolation trench 14T may have a lower bottom surface than that of the gate line trench 12T of the channel region CH. A first source/drain 11′ab and a second source/drain 11″ab may be arranged in an upper portion of the channel region CH located at both sides of the gate line trench 12T.

The gate stack 12 may be arranged inside the gate line trench 12T. For example, a gate insulating layer 12a, a gate electrode 12b, and a gate capping layer 12c may be sequentially arranged inside the gate line trench 12T. The gate insulating layer 12a and the gate electrode 12b may be the same as described above, and the gate capping layer 12c may include at least one of silicon oxide, silicon oxynitride, and silicon nitride. The gate capping layer 12c may be arranged on the gate electrode 12b to fill the remaining portion of the gate line trench 12T.

A bit line structure 13 may be disposed on the first source/drain 11′ab. The bit line structure 13 may be arranged parallel to the upper surface of the semiconductor substrate 11′ and extend in the Y direction. The bit line structure 13 may be electrically connected to the first source/drain 11′ab and may include a bit line contact 13a, a bit line 13b, and a bit line capping layer 13c, which are sequentially stacked on the semiconductor substrate 11′. For example, the bit line contact 13a may include polysilicon, the bit line 13b may include a metal material, and the bit line capping layer 13c may include an insulating material, such as silicon nitride or silicon oxynitride.

Although FIG. 15 illustrates that the bit line contact 13a has a bottom surface at the same level as the upper surface of the semiconductor substrate 11′, this is only an example and the disclosure is not limited thereto. For example, in another embodiment, a recess formed to a certain depth from the upper surface of the semiconductor substrate 11′ may be further provided. The bit line contact 13a may extend to the inside of the recess so that the bottom surface of the bit line contact 13a is lower than the upper surface of the semiconductor substrate 11′.

The bit line structure 13 may further include a bit line intermediate layer (not shown) between the bit line contact 13a and the bit line 13b. The bit line intermediate layer may include metal silicide, such as tungsten silicide, or metal nitride, such as tungsten nitride. In addition, a bit line spacer (not shown) may be further formed on a sidewall of the bit line structure 13. The bit line spacer may have a single-layer structure or a multilayer structure and may include an insulating material, such as silicon oxide, silicon oxynitride, or silicon nitride. In addition, the bit line spacer may further include an air space (not shown).

The contact structure 20′ may be disposed on the second source/drain 11″ab. The contact structure 20′ and the bit line structure 13 may be disposed on different sources/drains on the semiconductor substrate 11′. The contact structure 20′ may have a structure in which a lower contact pattern (not shown), a metal silicide layer (not shown), and an upper contact pattern (not shown) are sequentially stacked on the second source/drain 11′″ab. The contact structure 20′ may further include a barrier layer (not shown) surrounding the side surface and the bottom surface of the upper contact pattern. For example, the lower contact pattern may include polysilicon, the upper contact pattern may include a metal material, and the barrier layer may include a conductive metal nitride.

The capacitor CA3 may be disposed on the semiconductor substrate 11′ and electrically connected to the contact structure 20′. Specifically, the capacitor CA3 includes a first electrode 110 electrically connected to the contact structure 20′, a second electrode 140 apart from the first electrode 110, a dielectric layer 130 between the first electrode 110 and the second electrode 140, and a conductive interface layer 120 between the first electrode 110 and the dielectric layer 130. The first electrode 110 may have a cylindrical shape or a cup shape having an internal space with a closed bottom. The second electrode 140 may have a comb shape having comb teeth extending into an internal space formed by the first electrode 110 and a region between the adjacent first electrodes 110. In addition, the dielectric layer 130 may be arranged between the first electrode 110 and the second electrode 140 so as to be parallel to the surfaces of the first electrode 110 and the second electrode 140. The conductive interface layer 120 may be arranged between the first electrode 110 and the dielectric layer 130 so as to be parallel to the surfaces of the first electrode 110 and the dielectric layer 130. Because materials of the first electrode 110, the conductive interface layer 120, the dielectric layer 130, and the second electrode 140 constituting the capacitor CA3 are substantially the same as those of the capacitors 100 described with reference to FIGS. 1 to 10, detailed descriptions thereof are omitted.

An interlayer insulating layer 15 may be further arranged between the capacitor CA3 and the semiconductor substrate 11′. The interlayer insulating layer 15 may be arranged in a space between the capacitor CA3 and the semiconductor substrate 11′, in which other structures are not arranged. Specifically, the interlayer insulating layer 15 may be arranged to cover a wiring and/or electrode structure, such as the bit line structure 13, the contact structure 20′, and the gate stack 12 on the semiconductor substrate 11′. For example, the interlayer insulating layer 15 may surround a wall of the contact structure 20′. The interlayer insulating layer 15 may include a first interlayer insulating layer 15a surrounding the bit line contact 13a, and a second interlayer insulating layer 15b covering the side surfaces and/or the upper surfaces of the bit line 13b and the bit line capping layer 13c.

The first electrode 110 of the capacitor CA3 may be arranged on the interlayer insulating layer 15, specifically on the second interlayer insulating layer 15b. In addition, when a plurality of capacitors CA3 are arranged, bottom surfaces of a plurality of first electrodes 110 may be separated from each other by an etch stop layer 16. In other words, the etch stop layer 16 may include an opening 16T, and the bottom surface of the first electrode 110 of the capacitor CA3 may be arranged in the opening 16T. As illustrated, the first electrode 110 may have a cylindrical shape or a cup shape having an internal space with a closed bottom. The capacitor CA3 may further include a support (not shown) that prevents the first electrode 110 from being tilted or collapsed. The support may be disposed on the sidewall of the first electrode 110.

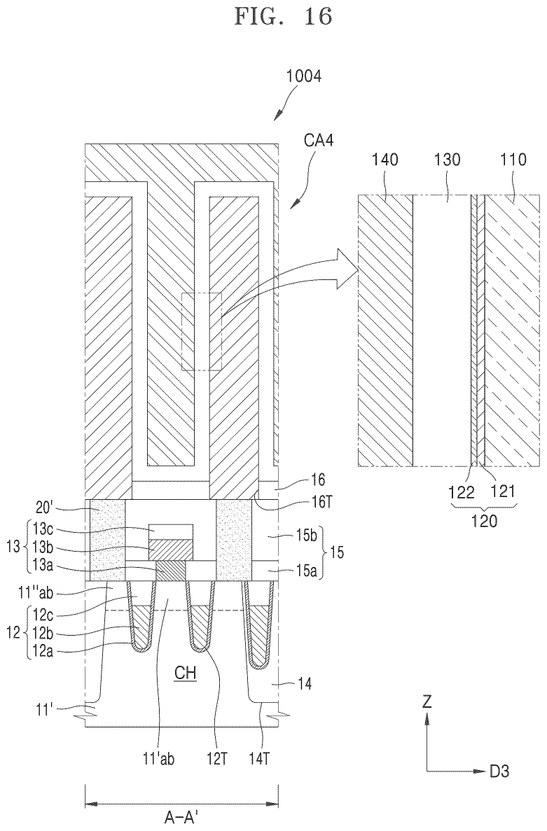

FIG. 16 is a cross-sectional view illustrating an electronic device 1004 according to another embodiment.

The cross-sectional view of the electronic device 1004 according to the present embodiment corresponds to the cross-sectional view taken along line A-A′ of FIG. 14, and the electronic device 1004 of FIG. 16 differs from the electronic device 1003 of FIG. 15 only in a shape of a capacitor CA4. The capacitor CA4 is disposed on a semiconductor substrate 11F and electrically connected to a contact structure 20′. The capacitor CA4 includes a first electrode 110 electrically connected to the contact structure 20′, a second electrode 140 apart from the first electrode 110, a dielectric layer 130 between the first electrode 110 and the second electrode 140, and a conductive interface layer 120 between the first electrode 110 and the dielectric layer 130. Materials of the first electrode 110, the conductive interface layer 120, the dielectric layer 130, and the second electrode 140 are substantially the same as those of the capacitors 100 described with reference to FIGS. 1 to 10.

The first electrode 110 may have a pillar shape, such as a cylinder, a square pillar, or a polygonal pillar, which extends in the vertical direction (Z direction). The second electrode 140 may have a comb shape having comb teeth extending into a region between the adjacent first electrodes 110. The dielectric layer 130 may be arranged between the first electrode 110 and the second electrode 140 so as to be parallel to the surfaces of the first electrode 110 and the second electrode 140. The conductive interface layer 120 may be arranged between the first electrode 110 and the dielectric layer 130 so as to be parallel to the surfaces of the first electrode 110 and the dielectric layer 130.

The capacitors and the electronic devices according to the embodiments described above may be applied to various application fields. For example, the electronic devices according to the embodiments may be applied as logic devices or memory devices. The electronic devices according to the embodiments may be used for arithmetic operations, program execution, temporary data retention, and the like in devices such as mobile devices, computers, laptop computers, sensors, network devices, and neuromorphic devices. In addition, the electronic devices according to the embodiments may be useful for devices in which an amount of data transmission is large and data transmission is continuously performed.

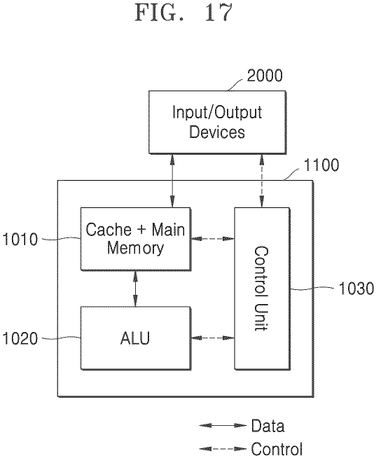

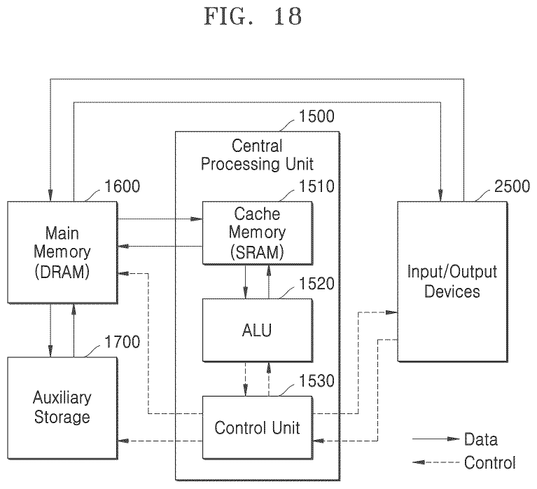

FIGS. 17 and 18 are conceptual diagrams schematically illustrating device architectures applicable to a device, according to at least one embodiment.

Referring to FIG. 17, an electronic device architecture 1100 may include a memory unit 1010, an arithmetic logic unit (ALU) 1020, and a control unit 1030. The memory unit 1010, the ALU 1020, and the control unit 1030 may be electrically connected to each other. For example, the electronic device architecture 1100 may be implemented as a single chip including the memory unit 1010, the ALU 1020, and the control unit 1030.

The memory unit 1010, the ALU 1020, and the control unit 1030 may be interconnected in an on-chip manner via a metal line to perform direct communication. The memory unit 1010, the ALU 1020, and the control unit 1030 may be monolithically integrated on a single substrate to constitute a single chip. Input/output devices 2000 may be connected to the electronic device architecture (chip) 1100. In addition, the memory unit 1010 may include both a main memory and a cache memory. The electronic device architecture (chip) 1100 may be an on-chip memory processing unit. The memory unit 1010 may include the capacitor and the electronic device including the same, which have been described above. The ALU 1020 or the control unit 1030 may also include the capacitor described above.

Referring to FIG. 18, a cache memory 1510, an ALU 1520, and a control unit 1530 may constitute a central processing unit (CPU) 1500. The cache memory 1510 may include a static random access memory (SRAM). Apart from the CPU 1500, a main memory 1600 and an auxiliary storage 1700 may be provided. The main memory 1600 may be a DRAM and may include the capacitor described above. In some cases, the electronic device architecture may be implemented in a form in which computing unit elements and memory unit elements are adjacent to each other on a single chip, without distinction of sub-units.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A capacitor comprising:
a first electrode;
a second electrode facing the first electrode;
a dielectric layer between the first electrode and the second electrode, the dielectric layer including a rutile-phase dielectric material; and
a conductive interface layer between the first electrode and the dielectric layer, the conductive interface layer comprising
a first conductive interface layer between the first electrode and the dielectric layer and including a conductive metal oxide material having a stable crystal structure in a rutile phase, and
a second conductive interface layer between the first conductive interface layer and the dielectric layer,
wherein a conduction band offset between the second conductive interface layer and the dielectric layer is greater than a conduction band offset between the first conductive interface layer and the dielectric layer.

2. The capacitor of claim 1, wherein the first conductive interface layer includes molybdenum oxide (MoO₂) doped with tin (Sn).

3. The capacitor of claim 2, wherein a concentration of the Sn in the first conductive interface layer is within a range of about 0.1 at % to about 5.0 at %.

4. The capacitor of claim 2, wherein a concentration of the Sn in the first conductive interface layer is within a range of about 0.1 at % to about 3.0 at %.

5. The capacitor of claim 1, wherein the first conductive interface layer has a thickness within a range of about 0.3 nm to about 4 nm.

6. The capacitor of claim 1, wherein the second conductive interface layer includes a second conductive metal oxide material having a stable crystal structure in a rutile phase.

7. The capacitor of claim 1, wherein the second conductive interface layer includes tin oxide (SnO₂), germanium oxide (GeO₂), or a mixture of tin oxide and germanium oxide ((SnxGe1-x)O2, 0<x<1).

8. The capacitor of claim 1, wherein the second conductive interface layer has a thickness within a range of about 0.3 nm to about 1 nm.

9. The capacitor of claim 1, wherein the dielectric layer includes rutile-phase titanium oxide (TiO₂).

10. The capacitor of claim 9, wherein the dielectric layer includes at least one of gallium (Ga), aluminum (Al), lanthanum (La), boron (B), indium (In), scandium (Sc), or yttrium (Y) as a dopant.

11. The capacitor of claim 10, wherein a concentration of the dopant in the dielectric layer is within a range of about 0 at % to about 20 at %.

12. The capacitor of claim 1, wherein the dielectric layer has a thickness within a range of about 3 nm to about 7 nm.

13. The capacitor of claim 1, wherein the first electrode includes at least one of titanium nitride (TiN), vanadium nitride (VN), niobium nitride (NbN), tantalum nitride (TaN), molybdenum nitride (MoN), cobalt nitride (CoN), or a combination thereof.

14. The capacitor of claim 1, wherein the first electrode has a thickness within a range of about 5 nm to about 10 nm.

15. A method of manufacturing a capacitor, the method comprising:
forming a first material layer on an upper surface of a first electrode, the first material layer including amorphous molybdenum oxide (MoOₓ);
forming a second material layer on an upper surface of the first material layer, the second material layer including tin oxide (SnO₂);
forming a first conductive interface layer including molybdenum oxide (MoO₂) doped with tin (Sn) by crystallizing the amorphous molybdenum oxide through a heat treatment;
forming a second conductive interface layer on the first conductive interface layer, the second conductive interface layer including tin oxide (SnO₂), germanium oxide (GeO₂), or a mixture of tin oxide and germanium oxide ((SnₓGe₁₋ₓ)O₂, 0<x<1);
forming a dielectric layer on the second conductive interface layer; and
forming a second electrode on the dielectric layer.

16. An electronic device comprising:
a transistor; and
a capacitor electrically connected to the transistor,
wherein the capacitor comprises
two electrodes facing each other,
a dielectric layer between the two electrodes, the dielectric layer including titanium oxide (TiO₂),
a molybdenum oxide (MoO₂) layer doped with tin (Sn) between one of the two electrodes and the dielectric layer, and
an interface layer including tin (Sn) oxide and/or germanium (Ge) oxide between the molybdenum oxide (MoO₂) layer doped with Sn and the dielectric layer.

17. The electronic device of claim 16, wherein a concentration of the Sn in the MoO₂ layer doped with Sn is within a range of about 0.1 at % to about 5.0 at %.

18. The electronic device of claim 17, wherein the concentration of the Sn in the MoO₂ layer doped with Sn is within a range of about 0.1 at % to about 3.0 at %.

19. The electronic device of claim 18, wherein the concentration of the Sn in the MoO₂ layer doped with Sn is within a range of about 0.5 at % to about 3.0 at %.

20. The electronic device of claim 16, wherein
the TiO₂ included in the dielectric layer is in a rutile phase, and
one of the two electrodes includes titanium nitride (TiN).
